(19) United States
(12) Patent Application Publication
(10) Pub. No.: US 2026/0169116 A1
(43) Pub. Date: Jun. 18, 2026

(54) SYSTEMS AND METHODS FOR ESTIMATING THE INCIDENT ANGLE OF AN ACOUSTIC WAVE

(71) Applicant: Toyota Motor Engineering & Manufacturing North America, Inc., Plano, TX (US)

(72) Inventors: Taehwa Lee, Ann Arbor, MI (US); Xiaopeng Li, Ann Arbor, MI (US); Ziqi Yu, Ann Arbor, MI (US)

(73) Assignees: Toyota Motor Engineering & Manufacturing North America, Inc., Plano, TX (US); Toyota Jidosha Kabushiki Kaisha, Toyota-shi (JP)

(21) Appl. No.: 18/980,402

(22) Filed: Dec. 13, 2024

(51) Int. Cl. G01S 3/802; G01R 19/10; G01R 19/165

(52) U.S. Cl. CPC G01S 3/802; G01R 19/10; G01R 19/16576

(57) ABSTRACT

Systems and methods for estimating the incident angle of an acoustic wave are presented herein. One embodiment is an incident-angle estimation system that includes at least two transducers that receive an acoustic wave and output alternating-current (AC) signals. The system also includes bandpass filters to produce bandpass-filtered AC signals from the AC signals. The system also includes rectifiers to convert the bandpass-filtered AC signals to direct-current (DC) voltages. In this embodiment, the system also includes a processor and a memory storing machine-readable instructions that, when executed by the processor, cause the processor to estimate the incident angle of the acoustic wave based on an analysis of the DC voltages. In another embodiment, an analog circuit to which the DC voltages are input produces an estimate of the incident angle.

### TECHNICAL FIELD

The subject matter described herein relates to systems and devices that process signals derived from acoustic waves and, more specifically, to systems and methods for estimating the incident angle of an acoustic wave.

### BACKGROUND

In a variety of applications, including robotics, the need for sound localization (determining the location of a sound source) arises. One aspect of sound localization is determining the direction from which a sound originates. This can include determining the incident angle (also referred to as the “angle of incidence”) of a received acoustic wave. Some conventional systems for estimating an acoustic incident angle rely on high-sample-rate data acquisition and digital signal processing components, which increases the cost of such systems.

### SUMMARY

Embodiments of a system for estimating the incident angle of an acoustic wave are presented herein. In one embodiment, the system comprises at least two transducers that receive an acoustic wave and output alternating-current (AC) signals. The system also includes bandpass filters to produce bandpass-filtered AC signals from the AC signals. The system also includes rectifiers to convert the bandpass-filtered AC signals to direct-current (DC) voltages. The system also includes a processor and a memory storing machine-readable instructions that, when executed by the processor, cause the processor to estimate the incident angle of the acoustic wave based on an analysis of the DC voltages.

Another embodiment of a system for estimating the incident angle of an acoustic wave comprises at least two transducers that receive an acoustic wave and output AC signals. The system also includes bandpass filters to produce bandpass-filtered AC signals from the AC signals. The system also includes rectifiers to convert the bandpass-filtered AC signals to DC voltages. The system also includes a divider to compute a voltage ratio between DC voltages associated with a pair of distinct transducers among the at least two transducers. The system also includes a subtractor to compute a difference between the voltage ratio and a predetermined offset value. The system also includes a multiplier to scale the difference by a predetermined scale factor. The resulting scaled difference is an analog estimate of the incident angle of the acoustic wave.

Another embodiment is a method of estimating the incident angle of an acoustic wave. The method includes bandpass filtering AC signals from at least two transducers that have received an acoustic wave to produce bandpass-filtered AC signals. The method also includes converting the bandpass-filtered AC signals to DC voltages. The method also includes estimating an incident angle of the acoustic wave based on an analysis of the DC voltages.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIGS. 1A and 1B illustrate a resonator and transducer portion of an incident-angle estimation system, in accordance with an illustrative embodiment of the invention.

FIG. 2 is a diagram of a first portion of an incident-angle estimation system, in accordance with an illustrative embodiment of the invention.

FIGS. 3A-3C are diagrams of a second portion of an incident-angle estimation system, in accordance with different embodiments of the invention.

FIG. 4 is a block diagram of a computing subsystem that forms part of an incident-angle estimation system, in accordance with illustrative embodiments of the invention.

FIG. 5 is flowchart of a method of estimating the incident angle of an acoustic wave, in accordance with illustrative embodiments of the invention.

To facilitate understanding, identical reference numerals have been used, wherever possible, to designate identical elements that are common to the figures. Additionally, elements of one or more embodiments may be advantageously adapted for utilization in other embodiments described herein.

### DETAILED DESCRIPTION

Various embodiments of an acoustic incident-angle estimation system described herein overcome the problem, with conventional systems, of increased cost due to components that support high-sample-rate data acquisition and subsequent digital signal processing. The various embodiments include at least two transducers that receive an acoustic wave and output alternating-current (AC) signals. The embodiments also include bandpass filters to produce bandpass-filtered AC signals from the AC signals. The embodiments further include rectifiers to convert the bandpass-filtered AC signals to direct-current (DC) voltages. In some embodiments, the rectifiers include a peak detector. The various embodiments estimate the incident angle of the acoustic wave based on an analysis of the DC voltages. The way in which the DC voltages are analyzed differs, depending on the embodiment.

Some embodiments include a computing subsystem (processor, memory, and machine-readable instructions) that analyzes the DC voltages. Some of those embodiments include a divider to compute one or more voltage ratios between DC voltages associated with pairs of distinct transducers among the at least two transducers. In these embodiments, the system maps the one or more voltage ratios to an estimate of the incident angle. For example, in one embodiment, the mapping involves consulting a lookup table relating the one or more voltage ratios to an estimate of the incident angle. In another embodiment, mapping the one or more voltage ratios to an estimate of the incident angle is based on a regression model (e.g., curve fit). In still other embodiments that include a computing subsystem, the analysis of the DC voltages involves inputting the DC voltages themselves to a trained machine-learning-based model that outputs an estimate of the incident angle.

In other embodiments, the system analyzes the DC voltages using analog circuitry. In those embodiments, the system includes a divider to compute a voltage ratio between DC voltages associated with a pair of distinct transducers among the at least two transducers. In these embodiments, the system also includes a subtractor to compute the difference between the voltage ratio and a predetermined offset value. In this embodiment, the system also includes a multiplier to scale the difference by a predetermined scale factor. The scaled difference is an analog estimate of the incident angle of the acoustic wave.

These various embodiments are discussed in further detail below.

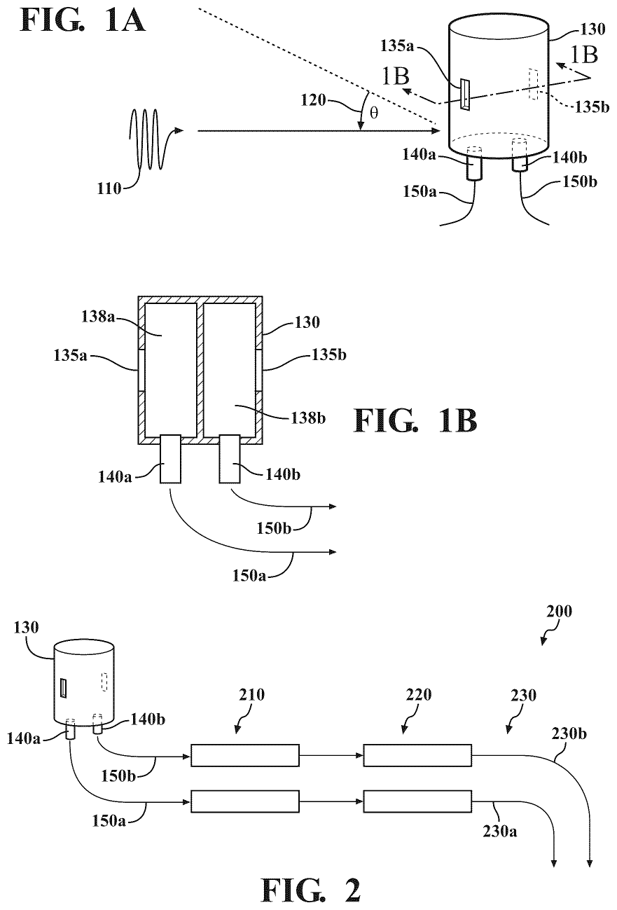

Referring to FIGS. 1A and 1B, they illustrate a resonator and transducer portion of an incident-angle estimation system, in accordance with an illustrative embodiment of the invention. As indicated in FIG. 1A, an acoustic wave 110 is received at a resonator 130 that includes a neck (open slot) 135a. The acoustic wave 110 arrives at the resonator 130 at an incident angle 120 denoted θ relative to a predetermined reference (the dotted line in FIG. 1A). In this example, the flat top surface of the resonator 130 is in the x-y plane, and the z-axis direction is up and down in FIG. 1A. Thus, the incident angle 120 (θ) is measured in the x-y plane. As shown in FIG. 1A, there are two transducers, 140a and 140b, associated with the resonator 130. Those transducers both receive the acoustic wave 110 and output respective AC signals 150 (150a and 150b).

As shown in the cross-sectional view 1B-1B of FIG. 1B, the resonator 130, in this embodiment, includes two resonant cavities, 138a and 138b, one for each transducer 140. The two resonant cavities 138a and 138b include respective necks 135a and 135b through which the acoustic wave 110 enters. As shown in FIG. 1B, each transducer 140 is disposed within a resonant cavity 138 of the resonator 130. In some embodiments, the transducers 140 are microphones, and the resonant cavities 138 are Helmholtz resonators.

FIG. 2 is a diagram of a first portion 200 of an incident-angle estimation system, in accordance with an illustrative embodiment of the invention. As shown in FIG. 2, the first portion 200 includes the resonator 130 and its associated transducers 140 discussed in connection with FIGS. 1A and 1B above. For simplicity, two transducers 140 are shown in FIG. 2, but in other embodiments there are more than two transducers 140, as discussed further below. As discussed above, the transducers 140 output AC signals 150. As shown in FIG. 2, the AC signals 150 are filtered by a set of bandpass filters 210 (one for each AC signal 150 output by a transducer 140) to produce bandpass-filtered AC signals. The bandwidth of the bandpass filters 210 varies, depending on the embodiment-specifically, depending on the acoustic frequency range of interest. For example, in one illustrative embodiment, the center frequency of each bandpass filter 210 is 2 kHz, and each bandpass filter 210 passes frequencies of 2 kHz±100 Hz while attenuating frequencies outside that range.

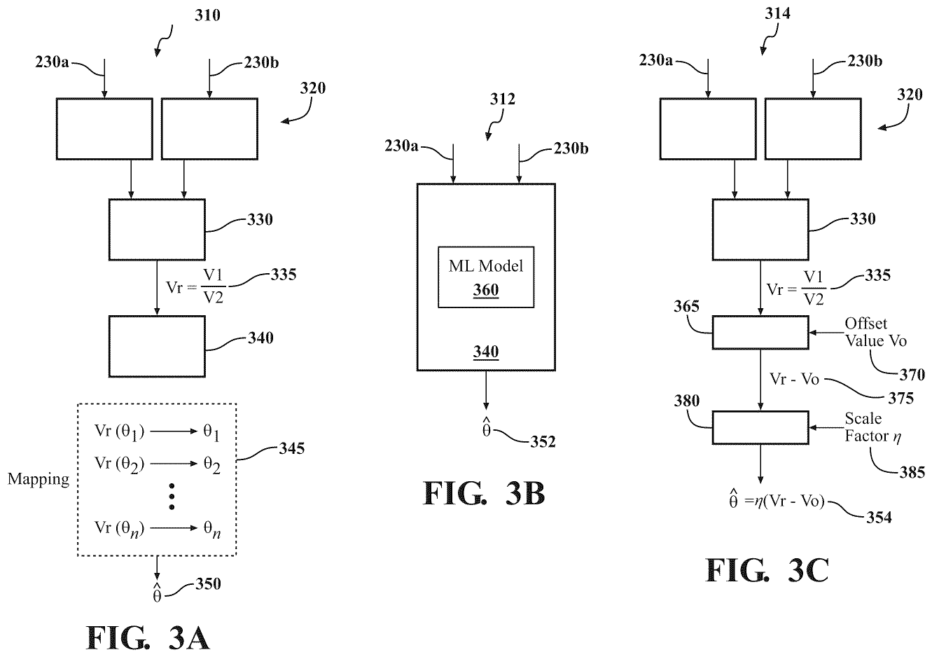

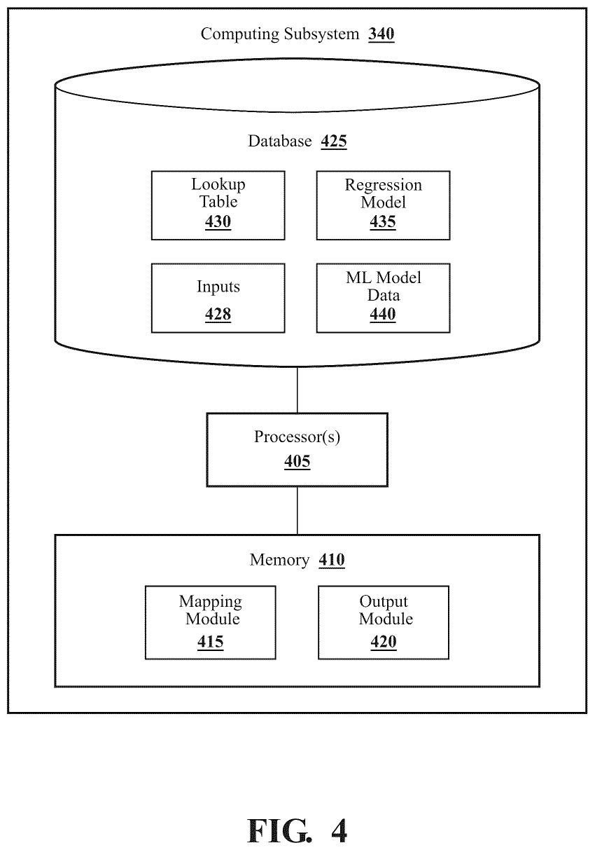

As shown in FIG. 2, the bandpass-filtered AC signals are input to a set of rectifiers 220 that convert the bandpass-filtered AC signals to DC voltages 230 (more specifically, DC voltages 230a and 230b in this example involving two transducers 140). As mentioned above, in some embodiments, the rectifiers include a peak detector. How the DC voltages 230 are subsequently processed and analyzed differs from embodiment to embodiment. Some of those different embodiments are described below in connection with FIGS. 3A-3C.

FIGS. 3A-3C are diagrams of a second portion (310, 312, 314) of an incident-angle estimation system, in accordance with different embodiments of the invention. Each of FIGS. 3A, 3B, and 3C corresponds to a different category of related embodiments.

In the category of embodiments illustrated in FIG. 3A, second portion 310 begins with the DC voltages 230 (230a and 230b, in this example) being input to a set of comparators 320. The purpose of the comparators 320, in these embodiments, is to ensure that each of the DC voltages 230a and 230b exceeds a predetermined voltage threshold. The voltage threshold depends on the amplitude of the acoustic wave 110 of interest. For example, in some applications, the threshold is a fraction of a volt. As those skilled in the art will understand, this threshold test is performed to avoid difficulties (e.g., division by a very small value) with the next block (divider 330), which computes the ratio of the two input DC voltages 230. The comparators 320 also ensure that the DC voltages 230 are sufficiently large to warrant further analysis. Let the DC voltage 230a be V₁ and the DC voltage 230b be V₂. In this embodiment, the divider 330 outputs the voltage ratio

$${V}_{r} = \frac{{V}_{1}}{{V}_{2}}$$

(335). In other embodiments, the divider 330 could output

$${V}_{r} = \frac{{V}_{2}}{{V}_{1}} ,$$

the reciprocal voltage ratio.

Via an interface that is not shown in FIG. 3A, a computing subsystem 340 (e.g., a processor or microcontroller, memory, and machine-readable instructions) digitizes the voltage ratio 335. Based on a previously completed calibration procedure, the computing subsystem 340 maps the voltage ratio 335 to an estimate of the incident angle 350 (\hat{θ}) via a voltage-ratio-to-incident-angle mapping 345. As discussed above, in some embodiments the mapping 345 is accomplished via a lookup table stored in the memory of computing subsystem 340. In other embodiments, a regression model (curve fit) is used to estimate the incident angle 120 (i.e., to produce the estimated incident angle 350) based on the voltage ratio 335.

In some variations of the category of embodiments illustrated in FIG. 3A, the number of transducers 140 is greater than two. In general, N transducers 140 can be employed, where N is greater than or equal to two. In these embodiments, a divider 330 (or set of dividers 330) computes one or more voltage ratios 335 between DC voltages 230 associated with pairs of distinct transducers 140 among the at least two transducers 140. For example, in the case of N=3, let the DC voltages 230 from the three transducers 140 be designated V₁, V₂, and V₃. The possible pairs of distinct transducers are V₁ and V₂, V₂ and V₃, and V₁ and V₃. A voltage ratio 335 and/or its reciprocal can be computed for each of these distinct pairs of DC voltages 230 or for fewer than all three distinct pairs, depending on the embodiment. In these embodiments, computing subsystem 340 maps the one or more voltage ratios to an estimate 350 of the incident angle 120. As discussed above, the mapping 345 can, for example, be via a lookup table or a regression model.

In a variation of the category of embodiments illustrated in FIG. 3A, one DC voltage 230 in each computed voltage ratio 335 is associated with (produced from) the same transducer 140 among the two or more transducers 140. For example, in an embodiment in which N=3, the incident-angle estimation system might compute the voltage ratios

$$\frac{{V}_{2}}{{V}_{1}} and \frac{{V}_{3}}{{V}_{1}}$$

and map those voltage ratios 335 to an estimate of the incident angle 120 based on a previously completed calibration procedure. In this example, the other two of the three DC voltages 230 are essentially normalized by the same DC voltage, V₁. One advantage of basing incident-angle estimates on DC voltage ratios is that computing a voltage ratio compensates for amplitude variations in the acoustic waves 110 that reach the incident-angle estimation system.

In the category of embodiments illustrated in FIG. 3B, second portion 312 begins with the DC voltages 230 (230a and 230b, in this example with two transducers 140) being digitized via an interface not shown in FIG. 3B and input to a differently configured computing subsystem 340. In this category of embodiments, the computing subsystem 340 includes a machine-learning-based (ML-based) model 360 that outputs an estimated incident angle 352 (\hat{θ}) based on the input DC voltages 230. For example, the ML model 360, depending on the embodiment, can include one or more neural networks that have been trained to process the DC voltages 230 and output the estimated incident angle 352. As those skilled in the art are aware, the process of training such a neural-network model can include, for example, supervised learning including ground-truth incident-angle data and a loss function that rewards accurate estimates of the incident angle 120 based on two or more input DC voltages 230.

The category of embodiments illustrated in FIG. 3B also generalizes to N transducers and their associated DC voltages 230, where N is greater than or equal to two. In such an embodiment, there are simply more DC voltages 230 that are input to the ML model 360.

In the category of embodiments illustrated in FIG. 3C, second portion 314, as in second portion 310, begins with the DC voltages 230 (230a and 230b) being input to a set of comparators 320. If the DC voltages 230a and 230b exceed the predetermined voltage threshold, as discussed above, divider 330 computes the ratio of the two DC voltages. As in second portion 310, let the DC voltage 230a be V₁ and the DC voltage 230b be V₂. In this embodiment, the divider 330 outputs the voltage ratio

$${V}_{r} = \frac{{V}_{1}}{{V}_{2}}$$

(335). In other embodiments, the divider 330 outputs

$${V}_{r} = \frac{{V}_{2}}{{V}_{1}}$$

(335, the reciprocal ratio). A subtractor 365 outputs the difference 375 between the voltage ratio 335 and a predetermined offset value 370: Vᵣ−Vₒ, where Vₒ is the offset value 370. A multiplier 380 scales the difference 375 by a predetermined scale factor 385 (η) to produce estimated incident angle 354 (\hat{θ}), an analog estimate of the incident angle 120. The estimated incident angle 354 is thus given by the following expression: \hat{θ}=η(Vᵣ−Vₒ) (354).

In the various embodiments described herein, analog components such as bandpass filters 210, rectifiers 220 (with or without a peak detector), comparators 320, divider 330, subtractor 365, and multiplier 380 can be implemented in ways that are well known to those skilled in the art. For example, as those skilled in the art are aware, a divider 330 can be implemented using an operational amplifier configured as a differential amplifier. An operational amplifier can also be configured to function as a subtractor 365. As an additional example, a multiplier 380 can be implemented using a Gilbert cell.

FIG. 4 is a block diagram of a computing subsystem 340 that forms part of an incident-angle estimation system, in accordance with illustrative embodiments of the invention. Examples of embodiments that include a computing subsystem 340 are discussed in greater detail above in connection with FIGS. 3A and 3B. In FIG. 4, computing subsystem 340 includes one or more processors 405 to which a memory 410 is communicably coupled. Memory 410 stores a mapping module 415 and an output module 420. The memory 410 is a random-access memory (RAM), read-only memory (ROM), a hard-disk drive, a flash memory, or other suitable non-transitory memory for storing the modules 415 and 420. The modules 415 and 420 are, for example, machine-readable instructions that, when executed by the one or more processors 405, cause the one or more processors 405 to perform the various functions disclosed herein.

As shown in FIG. 4, computing subsystem 340 can store various kinds of data in a database 425. For example, computing subsystem 340 can store, in the database 425, inputs 428, a lookup table 430, the parameters of a regression model 435, and ML model data 440. In the various embodiments described herein, only certain of these data items (inputs 428, lookup table 430, regression model parameters 435, and ML model data 440) are present in any one embodiment. In other words, in any given embodiment, one or more of those data items might not apply. Inputs 428 can include one or more computed DC voltage ratios 335 and/or two or more DC voltages 230 from corresponding transducers 140, depending on the embodiment. ML model data 440 can include hyperparameters, parameters, learned weights, etc., associated with a ML model (e.g., one or more neural networks).

Mapping module 415 generally includes machine-readable instructions that, when executed by the one or more processors 405, cause the one or more processors 405 to estimate the incident angle 120 of the acoustic wave 110 based on an analysis of the DC voltages 230. As explained above, the analysis of the DC voltages 230 differs, depending on the embodiment. In some embodiments (refer to FIG. 3A), the machine-readable instructions of mapping module 415, when executed by the one or more processors 405, cause the one or more processors 405 to map one or more input voltage ratios 335 to an estimate of the incident angle (350 or 352). As discussed above, such a mapping 345 can involve consulting a predetermined, stored lookup table 430. In other embodiments, the mapping of one or more voltage ratios 335 to an estimate of the incident angle (350 or 352) is accomplished using a regression model (e.g., curve fit).

In other embodiments, the inputs to computing subsystem 340 are digitized DC voltages 230 instead of one or more voltage ratios 335, and a trained ML-based model (e.g., one or more neural networks) that is part of mapping module 415 processes the DC voltages 230 and outputs an estimate of the incident angle (354). Such embodiments, including the process of training one or more neural networks, are discussed above in greater detail in connection with FIG. 3B.

Output module 420 generally includes machine-readable instructions that, when executed by the one or more processors 405, cause the one or more processors 405 to output (e.g., to another device, system, or user) whatever estimate (350 or 352) of the incident angle 120 mapping module 415 produces through the techniques described above.

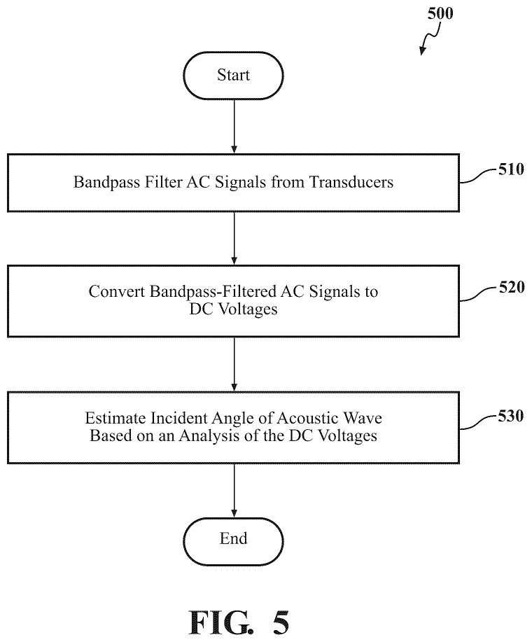

FIG. 5 is a flowchart of a method 500 of estimating the incident angle 120 of an acoustic wave 110, in accordance with illustrative embodiments of the invention. Method 500 will be discussed generally from the perspective of an incident-angle determination system that includes some version of first portion 200 discussed above in connection with FIG. 2 and second portion 310, 312, or 314 discussed above in connection with FIGS. 3A, 3B, and 3C, respectively. While method 500 applies to embodiments of an incident-angle estimation system, it should be appreciated that method 500 is not limited to being implemented within an embodiment of an incident-angle estimation system, but an embodiment of an incident-angle determination system is instead one example of a system that may implement method 500.

At block 510, bandpass filters 210 bandpass filter AC signals from at least two transducers 140 that have received an acoustic wave 110 to produce bandpass-filtered AC signals. As discussed above, the bandwidth of the bandpass filters 210 varies, depending on the embodiment-specifically, depending on the acoustic frequencies of interest. For example, in one illustrative embodiment, the center frequency of each bandpass filter 210 is 2 kHz, and each bandpass filter 210 passes frequencies of 2 kHz±100 Hz while attenuating frequencies outside that range.

At block 520, rectifiers 220 convert the bandpass-filtered AC signals to DC voltages. As mentioned above, in some embodiments, the rectifiers include a peak detector.

At block 530, the incident-angle estimation system estimates the incident angle 120 of the acoustic wave 110 based on an analysis of the DC voltages 230.

As described above, the analysis of the DC voltages 230 differs, depending on the embodiment. In some embodiments, the incident-angle estimation system includes a divider 330 to compute one or more voltage ratios 335 between DC voltages 230 associated with pairs of distinct transducers 140 among the at least two transducers 140. In some of these embodiments, the system includes a computing subsystem 340 that maps the one or more voltage ratios 335 to an estimate (350) of the incident angle 120. For example, in one embodiment, the mapping involves consulting a lookup table 430 relating the one or more voltage ratios 335 to an estimate (350) of the incident angle 120. In another embodiment, mapping the one or more voltage ratios 335 to an estimate (350) of the incident angle 120 is based on a regression model (e.g., curve fit). In still other embodiments that include a computing subsystem 340, the analysis of the DC voltages 230 involves inputting the DC voltages 230 themselves to a trained ML-based model 360 that outputs an estimate (352) of the incident angle 120.

In other embodiments, the incident-angle estimation system produces an estimate of the incident angle 120 using analog circuitry, as discussed above. In addition to a first portion 200 discussed above in connection with FIG. 2, these embodiments include a divider 330 to compute a voltage ratio 335 between DC voltages 230 associated with a pair of distinct transducers 140 among the at least two transducers 140. In these embodiments, the system also includes a subtractor 365 to compute the difference 375 between the voltage ratio 335 and a predetermined offset value 370. In this embodiment, the system also includes a multiplier 380 to scale the difference 375 by a predetermined scale factor 385. The scaled difference (354) is an analog estimate of the incident angle 120 of the acoustic wave 110.

The various embodiments of an incident-angle estimation system described herein have a variety of applications. Such a system can be constructed and deployed as an acoustic direction sensor, for example. Such a device has a variety of uses in robotics. For example, a children's robotic toy that automatically turns to face the child based on the direction from which the child's voice is coming could include such an acoustic direction sensor. Such a device can also be used, for example, in a service or companionship robot for humans of any age. In vehicles, such an acoustic direction sensor can be used to detect the direction, relative to an ego vehicle, in which an emergency vehicle emitting a siren is located. There are also numerous industrial applications for an acoustic incident-angle estimation system like the embodiments described herein. Depending on the embodiment, the frequency range of interest for an acoustic wave 110 can be within or beyond sounds that are audible to a human. For example, in some embodiments, the acoustic wave 110 is ultrasonic.

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1A-5, but the embodiments are not limited to the illustrated structure or application.

The components described above can be realized in hardware or a combination of hardware and software and can be realized in a centralized fashion in one processing system or in a distributed fashion where different elements are spread across several interconnected processing systems. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

In the description above, certain specific details are outlined in order to provide a thorough understanding of various implementations. However, one skilled in the art will understand that the invention may be practiced without these details. In other instances, well-known structures have not been shown or described in detail to avoid unnecessarily obscuring descriptions of the implementations. Unless the context requires otherwise, throughout the specification and claims which follow, the word “comprise” and variations thereof, such as, “comprises” and “comprising” are to be construed in an open, inclusive sense, that is, as “including, but not limited to.” Further, headings provided herein are for convenience only and do not interpret the scope or meaning of the claimed invention.

Reference throughout this specification to “one or more embodiments” or “an embodiment” means that a particular feature, structure or characteristic described in connection with the embodiment is included in at least one or more embodiments (implementations). Thus, the appearances of the phrases “in one or more embodiments” or “in an embodiment” in various places throughout this specification are not necessarily all referring to the same embodiment. Furthermore, the particular features, structures, or characteristics may be combined in any suitable manner in one or more embodiments or implementations. Also, as used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

The headings (such as “Background” and “Summary”) and sub-headings used herein are intended only for general organization of topics within the present disclosure and are not intended to limit the disclosure of the technology or any aspect thereof. The recitation of multiple implementations having stated features is not intended to exclude other implementations having additional features, or other implementations incorporating different combinations of the stated features. As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that an implementation can or may comprise certain elements or features does not exclude other implementations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one aspect, or various aspects means that a particular feature, structure, or characteristic described in connection with an implementation or particular system is included in at least one or more implementations or aspect. The appearances of the phrase “in one aspect” (or variations thereof) are not necessarily referring to the same aspect or implementation. It should also be understood that the various method steps discussed herein do not have to be carried out in the same order as depicted, and not each method step is required in each aspect or implementation.

Generally, “module,” as used herein, includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e. open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g. AB, AC, BC or ABC).

As used herein, “cause” or “causing” means to make, command, instruct, and/or enable an event or action to occur or at least be in a state where such event or action may occur, either in a direct or indirect manner.

Aspects herein can be embodied in other forms without departing from the spirit or essential attributes thereof. Accordingly, reference should be made to the following claims rather than to the foregoing specification, as indicating the scope hereof.

What is claimed is:

1. A system, comprising:
at least two transducers that receive an acoustic wave and output alternating-current (AC) signals;
bandpass filters to produce bandpass-filtered AC signals from the AC signals;
rectifiers to convert the bandpass-filtered AC signals to direct-current (DC) voltages;
a processor; and
a memory storing machine-readable instructions that, when executed by the processor, cause the processor to estimate the incident angle of the acoustic wave based on an analysis of the DC voltages.

2. The system of claim 1, wherein each of the at least two transducers is disposed within an acoustic resonator.

3. The system of claim 1, wherein the at least two transducers are microphones.

4. The system of claim 1, further comprising a divider to compute one or more voltage ratios between DC voltages associated with pairs of distinct transducers among the at least two transducers, wherein the machine-readable instructions include instructions that, when executed by the processor, cause the processor to map the one or more voltage ratios to an estimate of the incident angle.

5. The system of claim 4, further comprising a comparator to ensure, prior to the divider computing the one or more voltage ratios, that the DC voltages in each of the one or more voltage ratios exceed a predetermined voltage threshold.

6. The system of claim 4, wherein one DC voltage in each of the one or more voltage ratios is associated with the same transducer among the at least two transducers.

7. The system of claim 1, wherein the machine-readable instructions include instructions that, when executed by the processor, cause the processor to:
process the DC voltages using a trained machine-learning-based model; and
output, from the trained machine-learning-based model, an estimate of the incident angle.

8. The system of claim 1, wherein the rectifiers include a peak detector.

9. A system, comprising:
at least two transducers that receive an acoustic wave and output alternating-current (AC) signals;
bandpass filters to produce bandpass-filtered AC signals from the AC signals;
rectifiers to convert the bandpass-filtered AC signals to direct-current (DC) voltages;
a divider to compute a voltage ratio between DC voltages associated with a pair of distinct transducers among the at least two transducers;
a subtractor to compute a difference between the voltage ratio and a predetermined offset value; and
a multiplier to scale the difference by a predetermined scale factor, wherein the scaled difference is an analog estimate of the incident angle of the acoustic wave.

10. The system of claim 9, further comprising a comparator to ensure, prior to the divider computing the voltage ratio, that both DC voltages in the voltage ratio exceed a predetermined voltage threshold.

11. The system of claim 9, wherein each of the at least two transducers is a microphone that is disposed within an acoustic resonator.

12. A method, comprising:
bandpass filtering alternating-current (AC) signals from at least two transducers that have received an acoustic wave to produce bandpass-filtered AC signals;
converting the bandpass-filtered AC signals to direct-current (DC) voltages; and
estimating an incident angle of the acoustic wave based on an analysis of the DC voltages.

13. The method of claim 12, wherein each of the at least two transducers is disposed within an acoustic resonator.

14. The method of claim 12, wherein the at least two transducers are microphones.

15. The method of claim 12, wherein the analysis of the DC voltages includes:
computing one or more voltage ratios between DC voltages associated with pairs of distinct transducers among the at least two transducers; and
mapping the one or more voltage ratios to an estimate of the incident angle.

16. The method of claim 15, further comprising ensuring, prior to the computing the one or more voltage ratios, that the DC voltages in each of the one or more voltage ratios exceed a predetermined voltage threshold.

17. The method of claim 15, wherein one DC voltage in each of the one or more voltage ratios is associated with the same transducer among the at least two transducers.

18. The method of claim 12, wherein the analysis of the DC voltages includes:
processing the DC voltages using a trained machine-learning-based model; and
outputting, from the trained machine-learning-based model, an estimate of the incident angle.

19. The method of claim 12, wherein the analysis of the DC voltages includes:
computing a voltage ratio between DC voltages associated with a pair of distinct transducers among the at least two transducers;
subtracting an offset value from the voltage ratio to produce a difference; and
scaling the difference by a predetermined scale factor to produce an estimate of the incident angle.

20. The method of claim 19, wherein the computing the voltage ratio, subtracting the offset value, and scaling the difference are performed using analog circuitry.
